(19) United States
(12) Patent Application Publication
(10) Pub. No.: US 2022/0158046 A1
(43) Pub. Date: May 19, 2022

(54) Silicone Water Vapor Barrier Film

(71) Applicant: BenQ Materials Corporation, Taoyuan (TW)

(72) Inventors: Shih-Chieh Teng, Taoyuan (TW); Ju-Hui Huang, Taoyuan (TW)

(21) Appl. No.: 16/953,285

(22) Filed: Nov. 19, 2020

(30) Foreign Application Priority Data
Nov. 17, 2020 (TW) 109140131

(51) Int. Cl. H01L 33/56; C08J 5/18; C08J 7/048; C08J 7/04; C09D 183/04; C23C 14/02; C23C 14/34; C23C 16/02; C23C 16/455

(52) U.S. Cl. CPC H01L 33/56; C08J 5/18; C08J 7/048; C08J 7/0423; C09D 183/04; H01L 2933/005; C23C 14/34; C23C 16/02; C23C 16/45525; C08J 2367/02; C08J 2483/04; C23C 14/02

(57) ABSTRACT

A silicone water vapor barrier film is provided. The silicone water vapor barrier film includes a polyethylene terephthalate film; an inorganic coating layer disposed on a surface of the polyethylene terephthalate film; and a first silicone resin layer disposed on another surface of the polyethylene terephthalate film opposite to the inorganic coating layer. The first silicone resin layer is formed by curing a first curable silicone resin composition. The water vapor transmission rate (WVTR) of the silicone water vapor barrier film of the present invention is not greater than 0.5 gm⁻² day⁻¹, the coefficient of thermal expansion (CTE) at 25° C. to 50° C. of the silicone water vapor barrier film is in the range of 5 ppm/° C. to 10 ppm/° C., and the visible light transmittance of the silicone water vapor barrier film is greater than 93%.

### CROSS-REFERENCE TO RELATED APPLICATION

This application claims the priority benefit of Taiwanese Application Serial Number 109140131, filed on Nov. 17, 2020, which is incorporated herein by reference.

### TECHNICAL FIELD

The present disclosure is directed to a silicone water vapor barrier film for encapsulating optical semiconductor devices and particularly to a silicone water vapor barrier film for encapsulating light emitting diode (LED) devices.

### BACKGROUND OF THE INVENTION

Comparing to traditional lighting devices, LEDs are widely developed because they are advantages of small size, high lighting efficiency, long working life, high safety, high response time, rich colors, no heat radiation and no mercury or other poisons polluted to environment. LEDs can be widely used in lighting for buildings, consumptive handheld lighting devices, retailed displaying light devices and housing lighting devices.

Conventional LED package comprises a lead frame, a LED chip and an encapsulated gel. Silicone resins are widely used as the encapsulation gels because of their excellent heat-resistance and light-resistance. However, the Si—O—Si bonding angle in the silicone resin is large, which will result in poor water vapor barrier property of the silicone resin, and phosphors or quantum dots in the LED package will be prone to be wetted and led to the decay of color or emitting light. Although, it is known that the water vapor barrier property of the silicone resin can be enhanced by increasing the cross-link density thereof or adding nanoparticles, but the enhancing effect is limited. In addition, because of higher Coefficient of Thermal Expansion (CTE) of the silicone resin, which will result in greater thermal stress and cause a compact inorganic thin film not be easily formed on the surface of the silicone resin during the inorganic thin film coating process. Therefore, it is not suggested to enhance the water vapor barrier property of the silicone film by coating an inorganic thin film on the surface thereof.

It is known that polymer thin film, such as PET or PEN substrate, has better water vapor barrier property. However, the flexibility and the molding ability of PET or PEN are not good enough to be applied in high-end LEDs encapsulated by chip scale package technology.

Therefore, a novel silicone water vapor barrier film is demanded to provide enough water vapor barrier property and high workability for packaging LEDs, and maintain necessary optical properties for LED encapsulation.

### SUMMARY OF THE INVENTION

The present invention provides a silicone water vapor barrier film, which provides enough water vapor barrier property and high workability for packaging LEDs by so-called chip scale package (CSP) process, and maintains necessary optical properties such as high visible light transmittance.

The present invention provides a silicone water vapor barrier film, comprising: a PET (polyethylene terephthalate) film; an inorganic coating layer, disposed on a surface of the PET film; and a first silicon resin layer, disposed on another surface of the PET layer opposite to the inorganic coating layer, wherein the first silicon resin layer is formed by curing a first curable silicon resin composition; wherein the water vapor transmission rate (WVTR) of the silicone water vapor barrier film is not greater than 0.5 gm⁻² day⁻¹, the coefficient of thermal expansion (CTE) at 25° C. to 50° C. is in the range of 5 ppm/° C. to 10 ppm/° C., and the visible light transmittance is higher than 93%.

In one embodiment of the silicone water vapor barrier film, wherein the inorganic coating layer is formed on the surface of the PET film by sputtering deposition or atomic layer deposition (ALD).

In one embodiment of the present invention, wherein the thickness of the inorganic coating layer is in the range of 20 nm to 50 nm.

In one embodiment of the present invention, wherein the inorganic coating layer comprises silicon dioxide (SiO₂), aluminum oxide (Al₂O₃) or hafnium dioxide (HfO₂).

In one embodiment of the present invention, wherein the thickness of the PET film can be in the range of 5 μm to 40 μm.

In one embodiment of the present invention, wherein the first curable silicon resin composition can comprise: 10 to 25 parts by weight of a linear polysiloxane, wherein the average composition formula of the linear polysiloxane has at least one aryl group bonded to a silicon atom and two alkenyl groups bonded to a silicon atom; 40 to 55 parts by weight of a first silicone resin, the first silicone resin comprises at least following unit represented by the general formulas: R¹SiO_{3/2} and R²₂SiO_{2/2,} wherein R¹ and R² are independently substituted or unsubstituted alkyl group, substituted or unsubstituted alkenyl group, or substituted or unsubstituted aryl group, and the molar fraction of R¹SiO_{3/2} unit is present in the range of 0.60 to 0.75 in the general formula, and the molar ratio of the alkenyl groups bonded to Si atoms to the functional groups bonded to Si atoms is in the range of 0.03 to 0.15; 15 to 30 parts by weight of a second silicone resin, the second silicone resin comprises at least following units represented by the general formulas: R³SiO_{3/2} and R⁴₃SiO_{1/2}, wherein R³ and R⁴ are independently substituted or unsubstituted alkyl group, substituted or unsubstituted alkenyl group, or substituted or unsubstituted aryl group; 15 to 25 parts by weight of a polysiloxane having silicon-hydrogen bond represented by the general formula as HR⁵₂SiO(SiR⁶₂O)ₙSiR⁵₂H, wherein R⁵ is a substituted or unsubstituted alkyl group or hydrogen, R⁶ is a substituted or unsubstituted aryl group or alkyl group, n is an integer greater or equal to 0; and a platinum group metal catalyst.

In another embodiment of the present invention, wherein the first curable silicon resin composition can optionally comprise 10 to 40 parts by weight of microsheets.

In another embodiment of the present invention, wherein the aspect ratio of each microsheet is in the range of 10 to 200, and the length of each microsheet is in the range of 0.1 μm to 25 μm.

In another embodiment of the present invention, wherein the microsheet can be at least one of mica, clay, layered double hydroxide, calcium hydrogen phosphate and boron nitride, or combinations thereof.

In one embodiment of the present invention, wherein the thickness of the first silicon resin layer can be in the range of 5 μm to 100 μm.

In further another embodiment of the present invention, wherein the silicone water vapor barrier film can optionally further comprise a second silicon resin layer disposed on another surface of the inorganic coating layer opposite to the PET film, wherein the second silicon resin layer is formed by curing a second curable silicon resin composition.

In further another embodiment of the present invention, wherein the first curable silicon resin composition and the second curable silicon resin composition can be the same or different compositions.

In further another embodiment of the present invention, wherein the thickness of the second silicon resin layer can be in the range of 5 μm to 100 μm.

The present invention further provides an optical semiconductor device, which is encapsulated by one of above-mentioned silicone water vapor barrier films.

The present invention still further provides a method of manufacturing a silicone water vapor barrier film, comprising the steps of: providing a first curable silicon resin composition; pre-curing the first curable silicon resin composition; adhering the pre-cured first curable silicon resin composition on a surface of a PET (polyethylene terephthalate) film; curing the pre-cured first curable silicon resin composition coated on the surface of the PET (polyethylene terephthalate) film to form a first silicon resin layer; conducting a surface treatment to another surface of the PET (polyethylene terephthalate) film opposite to the first silicon resin layer; and forming an inorganic coating layer on the treated surface of the PET (polyethylene terephthalate) film.

In one embodiment of the method of the present invention, wherein the inorganic coating layer is formed by sputtering deposition or atomic layer deposition (ALD).

In one embodiment of the method of the present invention, wherein the step of pre-curing the first curable silicon resin composition is proceeded at a temperature between 70° C. and 90° C. for 5 minutes to 30 minutes.

In one embodiment of the method of the present invention, wherein the step of curing the pre-cured first curable silicon resin composition is proceeded at a temperature between 130° C. and 160° C. for 2 hours to 5 hours.

In another embodiment of the method of the present invention, wherein the method can further comprise a step of forming a second silicon resin layer on another surface of the inorganic coating layer opposite to the PET film, wherein the second silicon resin layer can be formed by curing a second curable silicon resin composition.

### BRIEF DESCRIPTION OF THE DRAWINGS

FIG. 1 is a cross-sectional view of a silicone water vapor barrier film according to one embodiment of this invention.

FIG. 2 is a cross-sectional view of a silicone water vapor barrier film according to another embodiment of this invention.

### DETAILED DESCRIPTION OF THE INVENTION

In the following detailed description, for purposes of explanation, numerous specific details are set forth in order to provide a thorough understanding of the disclosed embodiments. It will be apparent, however, that one or more embodiments may be practiced without these specific details.

It is apparent that departures from specific designs and methods described and shown will suggest themselves to those skilled in the art and may be used without departing from the spirit and scope of the invention. The present invention is not restricted to the particular constructions described and illustrated, but should be construed to cohere with all modifications that may fall within the scope of the appended claims.

Unless defined otherwise, all technical and scientific terms used herein have the same meaning as commonly understood by one of ordinary skill in the art to which this invention belongs. Generally, the nomenclature used herein and the laboratory procedures are well known and commonly employed in the art. Conventional methods are used for these procedures, such as those provided in the art and various general references. Where a term is provided in the singular, the inventors also contemplate the plural of that term. The nomenclature used herein and the laboratory procedures described below are those well-known and commonly employed in the art.

One aspect of this invention is to provide a silicone water vapor barrier film.

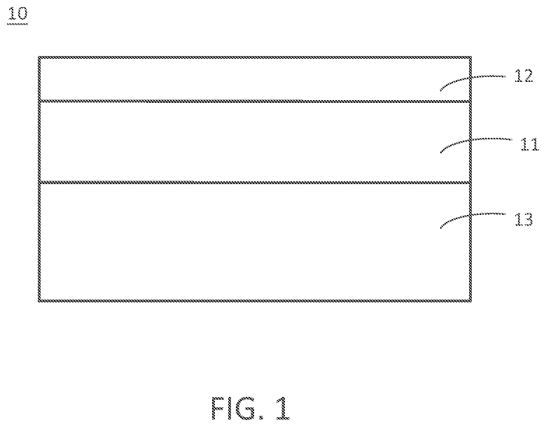

Please refer to FIG. 1, which illustrate a cross-sectional view of a silicone water vapor barrier film 10 according to one embodiment of this invention. The silicone water vapor barrier film 10 of the present invention has advantages of excellent water vapor barrier property and workability and maintains necessary optical properties. As shown in FIG. 1, the silicone water vapor barrier film 10 according to one embodiment of this invention comprises a PET (polyethylene terephthalate) film 11, an inorganic coating layer 12 and a first silicon resin layer 13. The water vapor transmission rate (WVTR) of the silicone water vapor barrier film 10 can be not greater than 0.5 gm⁻² day⁻¹, the coefficient of thermal expansion (CTE) at 25° C. to 50° C. can be in the range of 5 ppm/° C. to 10 ppm/° C., and the visible light transmittance can be higher than 93%.

In an embodiment of this invention, the thickness of the PET film 11 can be in the range of 5 μm to 40 μm, and preferably in the range of 5 μm to 10 μm. The water vapor barrier property of the silicone water vapor barrier film 10 of this invention is enhanced by the PET film 11, and the high visible light transmittance property necessary for LED encapsulation can still be maintained.

As shown in FIG. 1, the inorganic coating layer 12 is disposed on a surface of the PET film 11. The water vapor barrier property of the silicone water vapor barrier film 10 can be further enhanced by the inorganic coating layer 12. In one embodiment of this invention, the inorganic coating layer 12 can comprise, for example, but not limited to silicon dioxide (SiO₂), aluminum oxide (Al₂O₃) or hafnium dioxide (HfO₂). In one embodiment of this invention, the inorganic coating layer 12 can be an aluminum oxide (Al₂O₃) coating layer. In another embodiment of this invention, the inorganic coating layer 12 can be an aluminum oxide (Al₂O₃)/hafnium dioxide (HfO₂) coating layer.

In one embodiment of this invention, the inorganic coating layer 12 is formed on a surface of the PET film 11 by sputtering deposition or atomic layer deposition (ALD). The thickness of the inorganic coating layer 12 can be in the range of 20 nm to 50 nm, and preferably in the range of 20 nm to 30 nm.

As shown in FIG. 1, the first silicon resin layer 13 is disposed on another surface of the PET film 11 opposite to the inorganic coating layer 12. In an embodiment of this invention, the thickness of the first silicon resin layer 13 can be in the range of 5 μm to 100 μm, and preferably in the range of 5 μm to 50 μm. The first silicon resin layer 13 is formed by curing a first curable silicon resin composition.

According to one embodiment of this invention, the first curable silicon resin composition can comprise but not limited to: 10 to 25 parts by weight of a linear polysiloxane, the average composition formula of the linear polysiloxane has at least one aryl group bonded to a silicon atom and two alkenyl groups bonded to a silicon atom; 40 to 55 parts by weight of a first silicone resin, the first silicone resin comprises at least following unit represented by the general formulas: R¹SiO_{3/2} and R²₂SiO_{2/2}, wherein R¹ and R² are independently substituted or unsubstituted alkyl group, substituted or unsubstituted alkenyl group, or substituted or unsubstituted aryl group, and the molar fraction of R¹SiO_{3/2} unit is present in the range of 0.60 to 0.75 in the general formula, and the molar ratio of the alkenyl groups bonded to Si atoms to the functional groups bonded to Si atoms is in the range of 0.03 to 0.15; 15 to 30 parts by weight of a second silicone resin, the second silicone resin comprises at least following units represented by the general formulas: R³SiO_{3/2} and R⁴₃SiO_{1/2}, wherein R³ and R⁴ are independently substituted or unsubstituted alkyl group, substituted or unsubstituted alkenyl group, or substituted or unsubstituted aryl group; 15 to 25 parts by weight of a polysiloxane having silicon-hydrogen bond represented by the general formula as HR⁵₂SiO(SiR⁶₂O)ₙSiR⁵₂H, wherein R⁵ is a substituted or unsubstituted alkyl group or hydrogen, R⁶ is a substituted or unsubstituted aryl group or alkyl group, n is an integer greater or equal to 0; and a platinum group metal catalyst.

According to one embodiment of this invention, the first silicone resin comprises at least following unit represented by the general formulas: R¹SiO_{3/2} and R²₂SiO_{2/2}, wherein R¹ and R² are independently substituted or unsubstituted alkyl group, substituted or unsubstituted alkenyl group, or substituted or unsubstituted aryl group. The substituted or unsubstituted aryl group can be, such as, phenyl group, tolyl group, xylyl group, or naphthyl group, and preferably phenyl group. The substituted or unsubstituted alkenyl group can be, such as, vinyl group, acryl group, allyl group, butenyl group, pentenyl group, or hexenyl group, and preferably vinyl group. Except the substituted or unsubstituted aryl group and substituted or unsubstituted alkenyl group, those function groups bonded to Si atoms can be substituted or unsubstituted alkyl group, such as, methyl group, ethyl group, propyl group, butyl group, isobutyl group, tert-butyl group, pentyl group, neopentyl group, hexyl group, cyclohexyl group, octyl group, nonyl group or decyl group, and preferably methyl group.

According to one embodiment of this invention, in order to enhance the heat-resistance and hardness of the first silicon resin layer 13, in the average unit of first silicone resin, the molar ratio of the aryl groups bonded to Si atoms to all functional groups bonded to Si atoms, excluding the end-cap functional groups, is at least greater than 0.48. The weight average molecular weight of the first silicone resin can be in the range of 500 to 200,000, and preferably in the range of 1,000 to 190,000.

According to one preferred embodiment of this invention, the average unit of the first silicone resin can be represented as (PhSiO_{3/2})_{0.7}(Me₂SiO_{2/2})_{0.15}(ViMeSiO_{2/2})_{0.15} and end-capped with ViMe₂SiO_{1/2} unit. The above Ph represents phenyl group, Me represents methyl group, and Vi represents vinyl group.

According to another preferred embodiment of this invention, the average unit of the first silicone resin can be represented as (PhSiO_{3/2})_{0.7}(Me₂SiO_{2/2})_{0.2}(ViMeSiO_{2/2})_{0.1} and end-capped with ViMe₂SiO_{1/2} unit.

The linear polysiloxane is used for improving the processing of silicone resin of the first silicone resin and the second silicone resin and enhancing the flexibility of the obtained silicone water vapor barrier film 10. According to one embodiment of this invention, the average unit of the suitable linear polysiloxane comprises at least an aryl groups bonded to a silicon atom and an alkenyl group bonded to two silicon atoms. The aryl group can be a substituted or unsubstituted aryl group, such as, phenyl, tolyl, xylyl or naphthyl, and preferably phenyl. The alkenyl groups can be substituted or unsubstituted alkenyl groups, such as, vinyl, propenyl, allyl, butenyl, pentenyl or hexenyl, and preferably vinyl group. In addition to the aryl group and the alkenyl group, the groups bonded to silicon atoms can be substituted or unsubstituted alkyl groups, such as, methyl, ethyl, propyl, isopropyl, butyl, isobutyl, tert-butyl pentyl neopentyl, hexyl, cyclohexyl octyl, nonyl or decyl, and preferably methyl.

In order to enhance the heat-resistance, hardness and refractivity of the silicone water vapor barrier film 10, in the average composition formula of the linear polysiloxane in the first curable silicone resin, the molar ratio of the aryl groups bonded to Si atoms to all functional groups bonded to Si atoms, excluding the end-capped functional groups, is at least greater than 0.4. The content of the linear polysiloxane can be in the range of 10 to 25 parts by weight, and preferably 14 to 20 parts by weight.

In a preferred embodiment of the present invention, the average composition formula of the linear polysiloxane is represented as (PhMeSiO_{2/2})_{0.8}(Me₂SiO_{2/2})_{0.1}(ViMeSiO_{2/2})_{0.1} and end-capped with ViMe₂SiO_{1/2} unit, the above Ph represents phenyl group, Me represents methyl group and Vi represents vinyl group. The weight average molecular weight of the linear polysiloxane can be in the range of 1,000 to 200,000 and preferably in the range of 1,000 to 160,000. The viscosity of the linear polysiloxane at 25° C. is not limited and preferably in the range of 6,000 mPa·s to 10,000 mPa·s. In an embodiment of the present invention, the viscosity of the linear polysiloxane at 25° C. is 6420 mPa·s.

The average composition formula of the second silicone resin of the first curable silicon resin composition comprises at least R³SiO_{3/2} and R⁴₃SiO_{1/2}, wherein R³ is a substituted or unsubstituted aryl group, substituted or unsubstituted alkyl group, or substituted or unsubstituted alkenyl group. R⁴ is a substituted or unsubstituted aryl group, a substituted or unsubstituted alkyl group or a substituted or unsubstituted alkenyl group. The above mentioned substituted or unsubstituted aryl groups can be, for example, phenyl, tolyl, xylyl or naphthyl, and preferably phenyl. The substituted or unsubstituted alkenyl group can be, for example ethenyl, propenyl, allyl, butenyl, pentenyl or hexenyl, and preferably ethenyl. In addition to the above-mentioned substituted or unsubstituted aryl groups and the substituted or unsubstituted alkenyl groups, the other functional groups bonded to the silicon atom can be substituted or unsubstituted alkyl group, for example, methyl, ethyl, propyl, isopropyl, butyl, isobutyl, tert-butyl, pentyl, neopentyl, hexyl, cyclohexyl, octyl, nonyl or decyl, and preferably methyl.

For enhancing the heat-resistance and hardness of the silicone water vapor barrier film 10, in the second silicone resin of the first curable silicone resin composition, the molar ratio of the aryl groups bonded to silicon atom to the all functional groups bonded to the silicon atom, excluding the end-cap functional groups, is at least 0.25.

In a preferred embodiment of the present invention, the average composition formula of the second silicone resin can be represented by (PhSiO_{3/2})_{0.5}(ViMe₂SiO_{1/2})_{0.5}. The above Ph represents phenyl group, Me represents methyl group, and Vi represents vinyl group. The weight average molecular weight of the second silicone resin can be in the range of 100 to 10,000, and preferably in the range of about 500 to 5,000.

In the first curable silicone resin composition, the polysiloxane having silicon-hydrogen bond is represented as HR⁵₂SiO(SiR⁶₂O)ₙSiR⁵₂H, wherein R⁵ is substituted or unsubstituted alkyl groups or hydrogen, R⁶ is substituted or unsubstituted aryl groups or substituted or unsubstituted alkyl groups, and n is an integer greater or equal to 0.

The above-mentioned substituted or unsubstituted aryl group can be, such as, phenyl group, tolyl group, xylyl group, or naphthyl group, and preferably phenyl group. The above-mentioned substituted or unsubstituted alkyl group can be, such as, methyl group, ethyl group, propyl group, butyl group, isobutyl group, tert-butyl group, pentyl group, neopentyl group, hexyl group, cyclohexyl group, octyl group, nonyl group or decyl group, and preferably methyl group.

In a preferred embodiment of the present invention, the average unit formula of the polysiloxane having silicon-hydrogen bond can be represented as (Ph₂SiO_{2/2})₁(HMe₂SiO_{1/2})₂. The above Ph represents phenyl group and Me represents methyl group. The weight average molecular weight of the polysiloxane having silicon-hydrogen bond can be in the range of 100 to 5,000, and preferably in the range of 100 to 1,000.

Suitable platinum group metal catalyst can be, for example, platinum based catalyst, rhodium based catalyst or palladium based catalyst, and preferably is platinum based catalyst. The common used catalysts can be, for example, H₂PtCl₆.mH₂O, K₂PtCl₆, KHPtCl₆.mH₂O, K₂PtCl₄, K₂PtCl₄.mH₂O or PtO₂.mH₂O (m is an positive integer). The complex of these catalysts with olefin, alcohol or organopolysiloxane containing vinyl groups can be also used, for example, platinum(0)-2,4,6,8-tetramethyl-2,4,6,8-tetravinylcyclotetrasiloxane complex solution or Platinum-Octanal/Octanol complex, but not limited to these compounds. These platinum group metal catalysts can be used alone or in combination. The addition amount of the platinum group metal catalyst is in the range of about 1 ppm to 50 ppm on the total weight of the linear polysiloxane, the first silicone resin, the second silicone resin and the polysiloxane having silicon-hydrogen bond, and preferably is in the range of about 3 ppm to about 10 ppm.

According to one preferred embodiment of this invention, the platinum group metal catalyst is Platinum-Octanal/Octanol complex. The addition amount of the catalyst is about 4.3 ppm on the basis of the total weight of the linear polysiloxane, the first silicone resin, the second silicone resin and the polysiloxane having silicon-hydrogen bond.

According to another embodiment of this invention, the first curable silicon resin composition can optionally further comprise 10 to 40 parts by weight of microsheets to further reduce the coefficient of thermal expansion (CTE) of the silicone water vapor barrier film.

Suitable microsheets can be, for example, at least one of mica, clay, layered double hydroxide, calcium hydrogen phosphate and boron nitride, or combinations thereof. The aspect ratio of each suitable microsheet can be in the range of 10 to 200, and preferably in the range of 50 to 200. The length of each suitable microsheet can be in the range of 0.1 μm to 25 μm, and preferably in the range of 2 μm to 25 μm. The thickness of the suitable microsheet can be in the range of 10 nm to 1000 nm, and preferably in the range of 10 nm to 400 nm.

According to one preferred embodiment of this invention, the microsheets within the first curable silicone resin can be the microsheets modified by silicone to enhance its hydrophobic property to prevent microsheets within the first curable silicone resin from being aggregated. In a preferred embodiment of this invention, the microsheets within the curable silicone resin can be a methyl silicon modified mica microsheets.

The content of microsheets within the first curable silicone resin can be in the range of 10 to 40 parts by weight. When the content of microsheets within the first curable silicone resin is too high, the optical properties of the silicone water vapor barrier film will be affected. When the content of microsheets within the first curable silicone resin is too low, the Coefficient of Thermal Expansion (CTE) of the silicone water vapor barrier film can't be effectively decreased.

In addition, the first curable silicone resin composition according to this invention can further comprise a bonding agent, an inhibitor, a thixotropic agent, an anti-setting agent, an inorganic filler, a phosphor, a quantum dot or combinations thereof.

The above-mentioned inorganic fillers are used to enhance the heat-resistance of the silicone water vapor barrier film, and also be used as reflective particles. The inorganic fillers can be enhanced inorganic filler, for example, but not limited to fumed silica and gas-phase titanium dioxide, or non-enhanced inorganic fillers, for example, but not limited to calcium carbonate, silicon carbonate, titanium dioxide, titanium oxide and zinc oxide.

According to one embodiment of this invention, the first curable silicone resin composition further comprises 0.1 to 5 parts by weight of fumed silica relative to 100 parts by weight of the total amount of the linear polysiloxane, the first silicone resin, the second silicone resin and the polysiloxane having silicon-hydrogen bond.

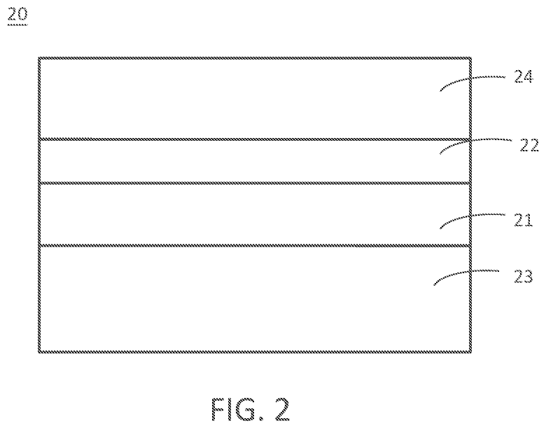

Please refer to FIG. 2, which illustrate a cross-sectional view of a silicone water vapor barrier film 20 according to another embodiment of this invention. The silicone water vapor barrier film 20 comprises a PET (polyethylene terephthalate) film 21, an inorganic coating layer 22, a first silicon resin layer 23 and a second silicon resin layer 24. Wherein the materials for the PET film 21, the inorganic coating layer 22 and the first silicon resin layer 23 are the same as the above mentioned materials for the PET film 11, the inorganic coating layer 12 and the first silicon resin layer 13, and no more repeated description will be described herein.

As shown in FIG. 2, the second silicon resin layer 24 is disposed on another surface of the inorganic coating layer 22 opposite to the PET film 21. In an embodiment of this invention, the thickness of the second silicon resin layer 24 can be in the range of 5 μm to 100 μm, and preferably in the range of 5 μm to 50 μm. The second silicon resin layer 24 is used to protect the inorganic coating layer 22 from being bended or scratched to avoid the water vapor barrier property of the silicon water vapor barrier film 20 being affected. In addition, by the second silicon resin layer 24, a semiconductor device can be encapsulated by the silicone water vapor barrier film 20 by vacuum bonding in the absence of additional adhesive.

According to one embodiment of this invention, the second silicon layer 24 is formed by curing a second curable resin composition. The second curable silicon resin composition and the above-mentioned first curable silicon resin composition can be of the same or different materials.

Another aspect of this invention is to provide an optical semiconductor device, which is encapsulated by one of the above-mentioned silicone water vapor barrier films.

Further another aspect of this invention is to provide a method of manufacturing a silicone water vapor barrier film.

Among the steps of the method of manufacturing a silicone water vapor barrier films, a first curable silicon resin composition is provided first. The first curable silicon resin composition is described as above, and no more repeated description will described herein.

Next, the first curable silicon resin composition is pre-cured at a temperature between 70° C. and 90° C., and preferably pre-cured at a temperature between 70° C. and 80° C., for 5 minutes to 30 minutes and preferably for 5 minutes to 10 minutes. In an embodiment of the method of this invention, the first curable silicon resin composition is pre-cured at 80° C. for 10 minutes.

After pre-cured, the pre-cured first silicon curable resin composition is adhered on a surface of a PET film. And then, the pre-cured first silicon curable resin composition on the surface of the PET film is cured to form a first silicon resin layer thereon. The temperature for curing the pre-cured first silicon curable resin composition can be between 130° C. and 160° C., and preferably between 150° C. and 160° C. The time for curing the pre-cured first silicon curable resin composition can be in the range of 2 hours to 5 hours, and preferably for 3 hours to 5 hours. In an embodiment of the method of this invention, the pre-cured first silicon curable resin composition is cured at 150° C. for 3 hours.

After the first silicon resin layer is formed, another surface of the PET film is surface treated to facilitate the formation of the inorganic coating layer. In an embodiment of the method of this invention, another surface of the PET film is surface treated by, for example, but not limited to O₂-plasma.

Finally, an inorganic coating layer is formed on the surface-treated another surface of the PET film. The inorganic coating layer can comprise but not limited to silicon dioxide (SiO₂), aluminum oxide (Al₂O₃) or hafnium dioxide (HfO₂). The inorganic coating layer can be formed by sputtering deposition or atomic layer deposition. The thickness of the inorganic coating layer can be in the range of 20 nm to 50 nm, and preferably in the range of 20 nm to 30 nm.

In another embodiment of the method of this invention, a second silicon resin layer can be optionally formed on another surface of the inorganic coating layer opposite to the PET film. The second silicon resin layer is formed by curing a second curable silicon resin composition. The second curable silicon resin composition and the first curable silicon resin composition can be of the same or different materials.

The silicone water vapor barrier film of this invention has excellent water vapor barrier property and appropriate optical properties, wherein the water vapor transmission rate (WVTR) thereof is not greater than 0.5 gm⁻² day⁻¹, and the visible light transmittance of the silicone water vapor barrier film is greater than 93%. Besides, silicone water vapor barrier film of this invention has excellent workability, wherein the coefficient of thermal expansion (CTE) at 25° C. to 50° C. thereof is in the range of 5 ppm/° C. to 10 ppm/° C.

The following examples are intended to further illustrate the invention, but the invention is not limited thereto.

### EXAMPLES

### Preparation Example 1

### Preparation of the Linear Polysiloxane (Compound 1)

3499.92 g (19.13 moles) of phenylmethyl dimethoxysilane (commercially available from Chembridge, Taiwan), 288.48 g (2.4 moles) of dimethyldimethoxysilane (commercially available from Chembridge, Taiwan), and 317.28 g (2.4 moles) of methylvinyldimethoxysilane (commercially available from Union Chemical Ind. Co., Ltd. (Union), Taiwan) were added to a reaction tank and mixed by stirring at ambient temperature to a homogenous solution. The mixed solution was dropped into a 5% aqueous sulfuric acid solution (5337.4 g) to obtain a reaction solution. Next, the reaction solution was heated to 75° C. to conduct a hydrolysis reaction. After the hydrolysis reaction was completed, the organic phase was extracted by deionized water until the organic phase reached a neutral state, and then removed the organic solvent to obtain a hydrolysis product.

The hydrolysis product, 69.52 g (0.374 mole) of divinyltetramethyldisiloxane (commercially available from Union) and 5.88 g of tetramethyl ammonium hydroxide (brand name L09658, commercially available from Alfa Aesar, USA) were placed into a reaction tank. Nitrogen was fed into the reaction tank and the mixture was stirred at ambient temperature to obtain a reaction solution. The reaction solution was heated to 95° C. After the reaction was completed, the reaction solution was conducted an alkaline removing to complete the preparation of Compound 1. The average composition formula of the Compound 1 is (PhMeSiO_{2/2})_{0.8}(Me₂SiO_{2/2})_{0.1}(ViMeSiO_{2/2})_{0.1} with end-capped unit ViMe₂SiO_{1/2}, wherein Ph represents phenyl group, Me represents methyl group and Vi represents vinyl group.

### Preparation Example 2

### Preparation of the First Silicone Resin (Compound 2)

2776 g (14 mole) of phenyl-trimethoxysilane (commercially available from Union, Taiwan), 480.88 g (4 moles) of dimethyl dimethoxysilane (commercially available from Chembridge, Taiwan), and 264.46 g (2 moles) of methylvinyldimethoxysilane (commercially available from Union, Taiwan) were placed in a reaction tank. The mixture was stirred at ambient temperature to obtain a homogenous solution. The mixed solution was dropped into 5% aqueous sulfuric acid solution to prepare a reaction solution. Then, this reaction solution was heated to 75° C. to conduct a hydrolysis reaction. After the reaction completed, the organic phase was extracted by deionized water until the organic phase reached neutral state, and then removed the solvent to obtain a hydrolysis product.

The hydrolysis product, 21.39 g (0.11 moles) of divinyltetramethyldisiloxane (commercially available from Union), 22.74 g of potassium hydroxide and 2274 g of toluene were placed into a reaction tank. Nitrogen was fed into the reaction tank and the mixture was stirred at ambient temperature to obtain a reaction solution. Next, the reaction solution was heated to 95° C. After the reaction was completed, the organic phase was extracted by deionized water until the organic phase reached neutral state, and then removed the solvent to obtain Compound 2. The average composition formula of Compound 2 was (PhSiO_{3/2})_{0.7}(Me₂SiO_{2/2})_{0.2}(ViMeSiO_{2/2})_{0.1} with end-capped unit ViMe₂SiO_{1/2}.

### Preparation Example 3

### Preparation of the First Silicone Resin (Compound 3)

2379.4 g (12 moles) of phenyl-trimethoxysilane (commercially available from Union, Taiwan) and 1118.4 g (6 moles) of divinyltetramethyldisiloxane (commercially available from Union, Taiwan) were placed into a reaction tank. The mixture was stirred at ambient temperature until obtaining a homogenous solution. The mixed solution was dropped into 5% aqueous sulfuric acid solution (4547.16 g) to prepare a reaction solution. Then, this mixture solution was heated to 75° C. to conduct hydrolysis. After the reaction was completed, the organic phase was extracted by deionized water until the organic phase reached neutral state, and next, removed solvent to obtain a hydrolysis product.

The hydrolysis product, 1998 g of toluene and 10 g of potassium hydroxide were placed into a reaction tank. Nitrogen was fed into the reaction tank and the mixture was stirred at ambient temperature to prepare a reaction solution. Then, the reaction solution was heated to 95° C. After the reaction was completed, the organic phase was extracted by deionized water until the organic phase reached neutral state and then, the solvent was removed to obtain Compound 3. The average composition formula of Compound 3 is (PhSiO_{3/2})_{0.5}(ViMe₂SiO_{1/2})_{0.5}.

### Preparation Example 4

### Preparation of the Second Silicone Resin (Compound 4)

3432.04 g (14 mole) of diphenyldimethoxysilane (commercially available from Union, Taiwan) and 1880.62 g (14 mole) of 1,1,3,3-Tetramethyldisiloxane (commercially available from Chembridge, Taiwan) were placed into a reaction tank. The mixture was stirred at ambient temperature until obtaining a homogenous solution. The mixed solution was dropped into 50% aqueous sulfuric acid solution (2669 g) to prepare a reaction solution. Then, this mixture solution was conducted hydrolysis at room temperature for 4 hours. After the reaction was completed, the organic phase was extracted by deionized water until the organic phase reached neutral state and next, removed solvent to obtain Compound 4. The average composition formula of Compound 4 is (Ph₂SiO_{2/2})_{0.33}(HMe₂SiO_{1/2})_{0.67}.

### Preparation Example 5

### Preparation of Polysiloxane Having Silicon-Hydrogen Bond (Compound 5)

2776 g (14 mole) of phenyltrimethoxysilane (commercially available from Union, Taiwan) and 1880.62 g (14 mole) of 1,1,3,3-Tetramethyldisiloxane (commercially available from Chembridge, Taiwan) were placed into a reaction tank. The mixture was stirred at ambient temperature until obtaining a homogenous solution. The mixed solution was dropped into 50% aqueous sulfuric acid solution (2669 g) to prepare a reaction solution. Then, this mixture solution was conducted hydrolysis at room temperature for 4 hours. After the reaction was completed, the organic phase was extracted by deionized water until the organic phase reached neutral state and next, removed solvent to obtain Compound 5. The average composition formula of Compound 5 is (PhSiO_{3/2})_{0.33}(HMe₂SiO_{1/2})_{0.67}

### Example 1

Firstly, 47.84 g of Compound 2, 19.53 g of Compound 3, 15.96 g of Compound 4, 2.05 g of Compound 5, 1000 ppm (based on 100 g of Compound 1, Compound 2, Compound 3, Compound 4 and Compound 5) of 1-ethynyl-cyclohexanol as an inhibitor, and 1.5 parts by weight of fumed silica (brand name TS-720, commercially available from Cabot Corp., USA) were placed into a reaction vessel to prepare a first solution. Into another reaction vessel, 14.53 g of Compound 1, and 4.3 ppm (based on 100 g of Compound 1, Compound 2, Compound 3, Compound 4 and Compound 5) of platinum-octanal/octanol complex (commercially available from Gelest, USA) were placed to prepare a second solution. The first solution, the second solution, and equal amount of above mentioned materials zirconium beads with a thickness of 0.3 mm were mixed and stirred thoroughly by a Planetary Centrifugal Mixer (Thinky ARV-310), and then coated on a release substrate and pre-cured at 80° C. for 10 minutes to form a pre-cured silicon resin composition. Then, the pre-cured silicon resin composition was adhered to a PET film with a thickness of 9 μm, and after cured at 80° C. for 15 minutes, cured at 150° C. for 3 hours thereafter to form a first silicon resin layer with a thickness of 41 μm on the surface of the PET film, the release substrate was peeled-off. Next, another surface of the PET film opposite to the first silicon resin layer was surface-treated by a O₂-plasma under a power of 50 W for 6 minutes, and an aluminum oxide (Al₂O₃)/hafnium dioxide (HfO₂) coating layer with a thickness of 30 nm was formed by atomic layered deposition (ALD) to obtain a silicon water vapor barrier film. The atomic layered deposition (ALD) was proceed by an atomic layered deposition (ALD) apparatus (i-SA, commercially obtained from Syskey Technology, Taiwan) using trimethylaluminum (Al(CH₃)₃) and tetrakis(ethylmethylamino)hafnium (TEMAHF) as precursors, water as an oxidant, high purity argon as a blowing gas and a carrier gas, and working under a temperature of 50° C. and a pressure of 1 Torr.

### Example 2

Firstly, 47.84 g of Compound 2, 19.53 g of Compound 3, 15.96 g of Compound 4, 2.05 g of Compound 5, 1000 ppm (based on 100 g of Compound 1, Compound 2, Compound 3, Compound 4 and Compound 5) of 1-ethynyl-cyclohexanol as an inhibitor, and 1.5 parts by weight of fumed silica (brand name TS-720, commercially available from Cabot Corp., USA) were placed into a reaction vessel to prepare a first solution. Into another reaction vessel, 14.53 g of Compound 1, and 4.3 ppm (based on 100 g of Compound 1, Compound 2, Compound 3, Compound 4 and Compound 5) of platinum-octanal/octanol complex (commercially available from Gelest, USA) were placed to prepare a second solution. The first solution, the second solution, 30 g of methyl silicone modified mica lamellas (commercially available from Alplus Company Limited, Taiwan), 30 g of toluene as solvent and equal amount of above mentioned materials zirconium beads with a thickness of 0.3 mm were mixed and stirred thoroughly by a Planetary Centrifugal Mixer (Thinky ARV-310), and then coated on a release substrate and pre-cured at 80° C. for 10 minutes to form a pre-cured silicon resin composition. Then, the pre-cured silicon resin composition was adhered to a PET film with a thickness of 9 μm, and after cured at 80° C. for 15 minutes, cured at 150° C. for 3 hours thereafter to form a first silicon resin layer with a thickness of 41 μm on a surface of the PET film, the release substrate was peeled-off. Next, another surface of the PET film opposite to the first silicon resin layer was surface-treated by a O₂-plasma under a power of 50 W for 6 minutes, and formed an aluminum oxide (Al₂O₃)/hafnium dioxide (HfO₂) coating layer with a thickness of 30 nm by atomic layered deposition (ALD) to obtain a silicon water vapor barrier film. The atomic layered deposition (ALD) was proceed by an atomic layered deposition (ALD) apparatus (i-SA, commercially obtained from Syskey Technology, Taiwan) using trimethylaluminum (Al(CH₃)₃) and tetrakis(ethylmethylamino)hafnium (TEMAHF) as precursors, water as an oxidant, high purity argon as a blowing gas and a carrier gas, and working under a temperature of 50° C. and a pressure of 1 Torr.

### Comparative Example 1

Firstly, 47.84 g of Compound 2, 19.53 g of Compound 3, 15.96 g of Compound 4, 2.05 g of Compound 5, 1000 ppm (based on 100 g of Compound 1, Compound 2, Compound 3, Compound 4 and Compound 5) of 1-ethynyl-cyclohexanol as an inhibitor, and 1.5 parts by weight of fumed silica (brand name TS-720, commercially available from Cabot Corp., USA) were placed into a reaction vessel to prepare a first solution. Into another reaction vessel, 14.53 g of Compound 1, and 4.3 ppm (based on 100 g of Compound 1, Compound 2, Compound 3, Compound 4 and Compound 5) of platinum-octanal/octanol complex (commercially available from Gelest, USA) were placed to prepare a second solution. The first solution, the second solution, 30 g of toluene as solvent and equal amount of above mentioned materials zirconium beads with a thickness of 0.3 mm were mixed and stirred thoroughly by a Planetary Centrifugal Mixer (Thinky ARV-310), and then coated on a release substrate and after cured at 80° C. for 15minutes and 150° C. for 3 hours to form a silicon resin layer with a thickness of 50 μm, the release substrate was peeled-off. Next, the silicon resin layer was surface-treated by a O₂-plasma under a power of 50 W for 6 minutes, and formed an aluminum oxide (Al₂O₃)/hafnium dioxide (HfO₂) coating layer with a thickness of 30 nm by atomic layered deposition (ALD) thereon to obtain a silicon water vapor barrier film. The atomic layered deposition (ALD) was proceed by an atomic layered deposition (ALD) apparatus (i-SA, commercially obtained from Syskey Technology, Taiwan) using trimethylaluminum (Al(CH₃)₃) and tetrakis(ethylmethylamino)hafnium (TEMAHF) as precursors, water as an oxygen, high purity argon as a blowing gas and a carrier gas, and working under a temperature of 50° C. and a pressure of 1 Torr.

The silicone water vapor barrier films according to this invention were measured by the evaluation methods as follows. The measurement results are shown in Table 1.

Measurement of Water Vapor Transmission Rate (WVTR)

The water vapor transmission rate (WVTR) was measured by Moconaquatran model 1 (Measurement range: 5-5×10⁻⁵ gm⁻² day⁻¹) according to ASTM F1249, at 25° C., with 90% relative humidity (RH). The sample size used for measurements was 0.5-5 cm².

Measurement of Coefficient of Thermal Expansion (CTE)

The Coefficient of Thermal Expansion (CTE) was measured by the Thermal Mechanical Analyzer (TMA from TA instrument) according to ASTM E831, at 30-100° C. increasing by 10° C./min at nitrogen environment, and under the tension of 0.0023 N.

Measurement of Transmittance (T %)

The transmittance between wavelength of 380-700 nm was measured by the Spectrophotometer U4100 (from Hitachi, Japan).

TABLE 1
The properties of silicone water vapor barrier
films of Examples 1-2 and Comparative Example 1

| | WVTR | 25-50° C. CTE | Transmittance |
|---|---|---|---|
| Table 1 | (gm⁻²day⁻¹) | (ppm/° C.) | (%) |
| Example 1 | 0.25 | 9.8 | 95.00 |
| Example 2 | 0.50 | 6.3 | 93.66 |
| Comparative | 7.53 | 92.2 | 96.45 |
| Example 1 | | | |

As the measurement results shown in Table 1, the water vapor transmission rate (WVTR) of the silicone water vapor barrier films of Examples 1 to 2 are both smaller than that of the silicone water vapor barrier film of Comparative Examples 1, and the transmittances of the silicone water vapor barrier films of Examples 1 to 2 are still greater than 93% which demonstrate that the silicone water vapor barrier films of Examples 1 to 2 have excellent optical properties. Moreover, as shown in Table 1, the Coefficient of Thermal Expansions (CTE) of the silicone water vapor barrier films of Examples 1 to 2 are both lower than that of the silicone water vapor barrier film of the Comparative Example 1, which demonstrate that the silicone water vapor barrier films of Examples 1 to 2 can provide better workability which is beneficial to subsequent semiconductor encapsulating process.

Although particular embodiments have been shown and described, it should be understood that the above discussion is not intended to limit the present invention to these embodiments. Persons skilled in the art will understand that various changes and modifications may be made without departing from the scope of the present invention as literally and equivalently covered by the following claims.

What is claimed is:

1. A silicone water vapor barrier film, comprising:
a PET (polyethylene terephthalate) film;
an inorganic coating layer, disposed on a surface of the PET film; and
a first silicon resin layer, disposed on another surface of the PET film opposite to the inorganic coating layer, wherein the first silicon resin layer is formed by curing a first curable silicon resin composition;
wherein the water vapor transmission rate (WVTR) of the silicone water vapor barrier film is not greater than 0.5 gm⁻² day⁻¹, the coefficient of thermal expansion (CTE) at 25° C. to 50° C. is in the range of 5 ppm/° C. to 10 ppm/° C., and the visible light transmittance is higher than 93%.

2. The silicone water vapor barrier film as claimed in claim 1, wherein the inorganic coating layer is formed on the surface of the PET film by sputtering deposition or atomic layer deposition (ALD).

3. The silicone water vapor barrier film as claimed in claim 1, the thickness of the inorganic coating layer is in the range of 20 nm to 50 nm.

4. The silicone water vapor barrier film as claimed in claim 1, wherein the inorganic coating layer comprises silicon dioxide (SiO₂), aluminum oxide (Al₂O₃) or hafnium dioxide (HfO₂).

5. The silicone water vapor barrier film as claimed in claim 1, wherein the thickness of the PET film is in the range of 5 μm to 40 μm.

6. The silicone water vapor barrier film as claimed in claim 1, wherein the first curable silicon resin composition comprises:
10 to 25 parts by weight of a linear polysiloxane, wherein the average composition formula of the linear polysiloxane has at least one aryl group bonded to a silicon atom and two alkenyl groups bonded to a silicon atom;
40 to 55 parts by weight of a first silicone resin, the first silicone resin comprises at least following unit represented by the general formulas: R¹SiO_{3/2} and R²₂SiO_{2/2}, wherein R¹ and R² are independently substituted or unsubstituted alkyl group, substituted or unsubstituted alkenyl group, or substituted or unsubstituted aryl group, and the molar fraction of R¹SiO_{3/2} unit is present in the range of 0.60 to 0.75 in the general formula, and the molar ratio of the alkenyl groups bonded to Si atoms to the functional groups bonded to Si atoms is in the range of 0.03 to 0.15;
15 to 30 parts by weight of a second silicone resin, the second silicone resin comprises at least following units represented by the general formulas: R³SiO_{3/2} and R⁴₃SiO_{1/2}, wherein R³ and R⁴ are independently substituted or unsubstituted alkyl group, substituted or unsubstituted alkenyl group, or substituted or unsubstituted aryl group;
15 to 25 parts by weight of a polysiloxane having silicon-hydrogen bond represented by the general formula as HR⁵₂SiO(SiR⁶₂O)ₙSiR⁵₂H, wherein R⁵ is a substituted or unsubstituted alkyl group or hydrogen, R⁶ is a substituted or unsubstituted aryl group or alkyl group, n is an integer greater or equal to 0; and
a platinum group metal catalyst.

7. The silicone water vapor barrier film as claimed in claim 6, wherein the first curable silicon resin composition further comprises 10 to 40 parts by weight of microsheets.

8. The silicone water vapor barrier film as claimed in claim 7, wherein the aspect ratio of each microsheet is in the range of 10 to 200, and the length of each microsheet is in the range of 0.1 μm to 25 μm.

9. The silicone water vapor barrier film as claimed in claim 7, wherein the microsheet is selected from at least one of the group consisting of mica, clay, layered double hydroxide, calcium hydrogen phosphate and boron nitride, or combinations thereof.

10. The silicone water vapor barrier film as claimed in claim 1, wherein the thickness of the first silicon resin layer is in the range of 5 μm to 100 μm.

11. The silicone water vapor barrier film as claimed in claim 1, further comprising a second silicon resin layer disposed on another surface of the inorganic coating layer opposite to the PET film, wherein the second silicon resin layer is formed by curing a second curable silicon resin composition.

12. The silicone water vapor barrier film as claimed in claim 11, wherein the first silicon resin layer and the second silicon resin layer are of the same or different compositions.

13. The silicone water vapor barrier film as claimed in claim 11, wherein the thickness of the second silicon resin layer is in the range of 5 μm to 100 μm.

14. An optical semiconductor device, which is encapsulated by the silicone water vapor barrier film as claimed in claim 1.

15. A method of manufacturing a silicone water vapor barrier film, comprising the steps of:
providing a first curable silicon resin composition;
pre-curing the first curable silicon resin composition;
adhering the pre-cured first curable silicon resin composition on a surface of a PET (polyethylene terephthalate) film;
curing the pre-cured first curable silicon resin composition coated on the surface of the PET (polyethylene terephthalate) film to form a first silicon resin layer;
applying a surface treatment to another surface of the PET (polyethylene terephthalate) film opposite to the first silicon resin layer; and
forming an inorganic coating layer on the surface-treated another surface of the PET (polyethylene terephthalate) film.

16. The method as claimed in claim 15, wherein the inorganic coating layer is formed by sputtering deposition or atomic layer deposition (ALD).

17. The method as claimed in claim 15, wherein the step of pre-curing the first curable silicon resin composition is proceeded at a temperature between 70° C. and 90° C. for 5 minutes to 30 minutes.

18. The method as claimed in claim 15, wherein the step of curing the pre-cured first curable silicon resin composition is proceeded at a temperature between 130° C. and 160° C. for 2 hours to 5 hours.

19. The method as claimed in claim 15, further comprising a step of forming a second silicon resin layer on another surface of the inorganic coating layer opposite to the PET film, wherein the second silicon resin layer is formed by curing a second curable silicon resin composition.
